(19) United States
(12) Patent Application Publication
(10) Pub. No.: US 2026/0190231 A1
(43) Pub. Date: Jul. 2, 2026

(54) STACKED POWER SUPPLY ASSEMBLY

(71) Applicant: NVIDIA CORPORATION, Santa Clara, CA (US)

(72) Inventors: Sien CHEN, Shenzhen, Guangdong (CN); Xuan WANG, Shenzhen, Guangdong (CN); Chao CHEN, Shenzhen, Guangdong (CN); Junhong SUN, Shenzhen, Guangdong (CN); Xiang ZHU, Shenzhen, Guangdong (CN); Xin YANG, Shenzhen, Guangdong (CN); Xiangyang AN, Shenzhen, Guangdong (CN)

(21) Appl. No.: 18/572,156

(22) PCT Filed: Nov. 17, 2023
(86) PCT No.: PCT/CN2023/132233

§ 371 Date: Dec. 19, 2023

(51) Int. Cl. H05K 1/14; H05K 1/02; H05K 1/181

(52) U.S. Cl. CPC H05K 1/144; H05K 1/0203; H05K 1/181; H05K 2201/042; H05K 2201/064; H05K 2201/066; H05K 2201/10015; H05K 2201/1003; H05K 2201/10053

(57) ABSTRACT

Disclosed is a power supply assembly comprising a first printed circuit board (PCB), a second PCB that is vertically spaced apart from the first PCB, and a switch supported on the second PCB. The power supply assembly further comprises a conductive pillar that couples the first PCB to the second PCB, wherein current output by the switch flows from the switch to the first PCB via the conductive pillar.

### BACKGROUND

### Field of the Various Embodiments

Embodiments of the present disclosure relate generally to electrical engineering and electronics and, more specifically, to stacked power supply assemblies.

### DESCRIPTION OF THE RELATED ART

Various high-performance computing systems and devices, including datacenter server machines, storage systems, graphics processors, and personal computers, incorporate different electronic components, such as processors, memory, high-current application-specific integrated circuits (ASICs) and/or field programmable gate arrays (FPGAs), that demand large amounts of power during operation.

Traditionally, single-phase power supplies, such as single-phase buck converters, boost converters, and flyback converters, have been implemented in high-performance computing systems and devices to power these types of electronic components. However, conventional single-phase power supply designs have struggled to keep pace with the increasing power demands (e . . . , 100 watts, 200 watts, or more) of the electronic components included in high-performance computing systems and devices.

In an effort to address the shortcomings of conventional single-phase power supplies, multiphase power supplies have become more prevalent in high-performance computing systems and devices. When compared to single-phase power supplies, multiphase power supplies can deliver larger amounts of power (e . . . , 300 watts, 400 watts, or more) to the different electronic components in a computing system or device far more efficiently. In conventional multiphase power supply designs, the power components, such as the phase switches, capacitors, and inductors, are typically mounted to or otherwise supported on the same printed circuit board (PCB) as the load (e . . . , the electronic component) that is being powered by the multiphase power supply. For example, in some designs, the phase switches, capacitors, and inductors are arranged on the PCB to surround the load that is being powered.

One drawback of the above designs, however, is that the numerous power components included in a multiphase power supply end up occupying too much space on the PCB. Consequently, when the size of the PCB is increased to accommodate the numerous power components included in a multiphase power supply, fitting the larger PCB into newer and smaller high-performance computing systems and devices becomes more difficult. Further, efficiently removing the heat generated by the electronic and power components on a larger PCB by forcing air over the PCB via one or more fans is difficult because the larger PCB surface area impedes the flow of the forced air, which results in hot air recirculating within the computing system or device in which the PCB is installed. In addition, because the inductors and capacitors in a multiphase power supply occupy larger amounts of physical space on a PCB, many of the phase switches included in a conventional multiphase power supply have to be arranged on the PCB farther away from the load to which the phase switches are supplying power. Consequently, the lengths of the conductors along which current flows from the phase switches to the load have to be increased, which increases the copper losses and the overall response times of the multiphase power supply.

As the foregoing illustrates, what is needed are more effective power supply designs.

### SUMMARY

Various embodiments set forth stacked power supply assemblies.

One embodiment of the present disclosure sets forth a power supply assembly comprising a first printed circuit board (PCB), a second PCB that is vertically spaced apart from the first PCB, and a switch supported on the second PCB. The power supply assembly further comprises a conductive pillar that couples the first PCB to the second PCB, wherein current output by the switch flows from the switch to the first PCB via the conductive pillar.

At least one technical advantage of the disclosed stacked power supply assemblies relative to the prior art is that, in the disclosed designs, the surface areas of the PCBs included in the stacked power supply assemblies are reduced. Accordingly, the phase switches can be positioned closer to the load to which the phase switches deliver power, thereby reducing the amount of copper losses in the disclosed stacked power supply assembly. Moreover, the reduced surface areas of the PCBs reduces the impedance experienced by the cooling air forced over the stacked power supply assembly by a fan, which improves the overall thermal efficiency of the disclosed stacked power supply assembly. Another technical advantage of the disclosed design is that the power components, such as phase switches, inductors, and capacitors, and the load powered by those power components are supported on different PCBs. Consequently, an increased number of decoupling capacitors can be positioned near the load, which lowers the resistance and improves the overall transient performance of the disclosed stacked power supply assembly. In addition, because of the use of different PCBs in the disclosed stacked power supply assembly, the PCB that supports the power components can be constructed from materials that are better suited for overall power delivery. These technical advantages represent one or more technological improvements over prior art approaches.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a conceptual block diagram of a stacked power supply assembly, according to various embodiments.

FIG. 2 illustrates an exemplar stacked power supply assembly, according to various embodiments.

FIG. 3 is a more detailed illustration of a top surface of a first PCB included in the exemplar stacked power supply assembly of FIG. 2, according to various embodiments.

FIG. 4 is a more detailed illustration of a bottom surface of the first PCB included in the exemplar stacked power supply assembly of FIG. 2, according to various embodiments.

FIG. 5 is a more detailed illustration of a top surface of a second PCB included in the exemplar stacked power supply assembly of FIG. 2, according to various embodiments.

FIG. 6 is a more detailed illustration of a bottom surface of the second PCB included in the exemplar stacked power supply assembly of FIG. 2, according to various embodiments.

FIGS. 7A-7C illustrate different exemplar conductive pillar structures that can be implemented in a stacked power supply assembly, according to various embodiments.

FIG. 8 illustrates a cooling system for a stacked power supply assembly, according to various embodiments.

FIG. 9 illustrates a computer system configured to implement one or more aspects of the various embodiments.

### DETAILED DESCRIPTION

In the following description, numerous specific details are set forth to provide a more thorough understanding of the embodiments of the present disclosure. However, it will be apparent to one of skill in the art that the embodiments of the present disclosure may be practiced without one or more of these specific details.

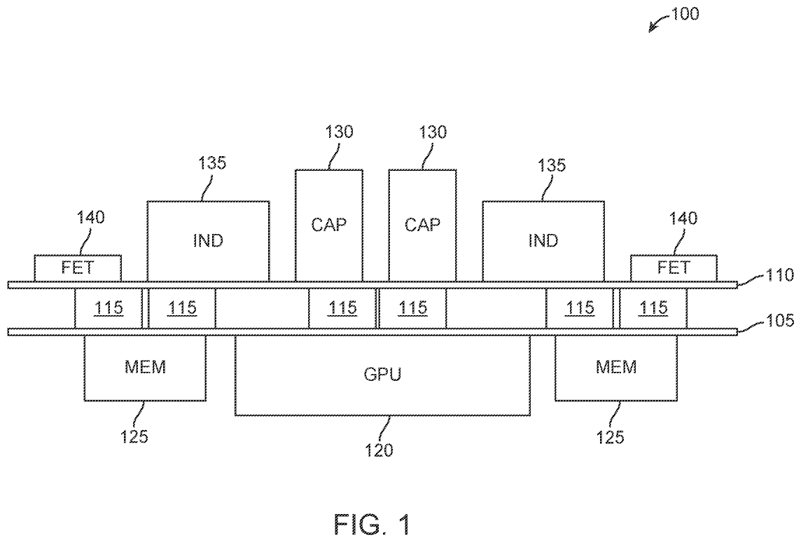

FIG. 1 illustrates a conceptual block diagram of a stacked power supply assembly 100, according to various embodiments. As shown, the stacked power supply assembly 100 includes a first printed circuit board (PCB) 105 and a second PCB 110. The first PCB 105 is vertically spaced apart from the second PCB 110 by a plurality of conductive pillars 115 that electrically couple the first PCB 105 to the second PCB 110. In some examples, the conductive pillars 115 are coupled between respective terminals, such as conductive pads, tabs, and/or traces, on the first and second PCBs 105, 110. In the illustrated example of FIG. 1, the stacked power supply assembly 100 includes six conductive pillars 115. However, persons skilled in the art will understand that the stacked power supply assembly 100 can include more than or fewer than six conductive pillars 115. For example, the stacked power assembly 100 can include one, two, three, four, five, seven, eight, twelve, or some other number of conductive pillars 115. In some examples, the conductive pillars 115 are constructed from copper. In other examples, the conductive pillars 115 can be constructed from copper and/or one or more other conductive materials.

In operation, the stacked power supply assembly 100 can provide power to one or more electronic components mounted to or otherwise supported by the first PCB 105. Electronic components mounted to the first PCB 105 can be electrically coupled to each other and/or the conductive pillars 115 via the first PCB 105. In some examples, the stacked power supply assembly 100 is implemented as a module that includes the one or more electronic components mounted to the first PCB 105. In other examples, the stacked power supply assembly 100 does not include any electronic components mounted to the first PCB 105. In such examples, one or more electronic components can be mounted to or otherwise coupled to the first PCB 105 after construction and/or installation of the stacked power supply assembly 100.

In the illustrated example of FIG. 1, a graphics processing unit (GPU) 120 and memory units 125 are mounted to the first PCB 105. However, persons skilled in the art will understand that, in other examples, the first PCB 105 can support one or more other electronic components such as, but not limited to, one or more other processors (e.g., central processing units (CPUs), GPUs, etc.), high-current application-specific integrated circuits (ASICs), field programmable gate arrays (FPGAs). Moreover, persons skilled in the art will understand that, in some examples, fewer electronic components or more electronic components than the number of electronic components shown in the illustrated example of FIG. 1 can be mounted to or otherwise supported by the first PCB 105.

In operation, electronic components supported on the first PCB 105 receive power from one or more power components mounted to or otherwise supported by the second PCB 110. The power components mounted to the second PCB 110 can be electrically coupled to each other and/or the conductive pillars 115 by the second PCB 110. Moreover, the power components mounted to the second PCB are electrically coupled to the first PCB 105 and the electronic components mounted to the first PCB 105 (e.g., GPU 120 and memory units 125) via the conductive pillars 115. In this regard, the power components mounted to the second PCB 110 can provide operational power to the electronic components mounted to the first PCB 105 via the conductive pillars 115. In some examples, the power components mounted to the second PCB 110 are included in a multiphase power supply that is mounted to the second PCB 110. In such examples, the multiphase power supply mounted to the second PCB 110 is configured to provide power to the GPU 120 and/or the memory units 125. In other examples, the power components mounted to the second PCB 110 are included in a different type of power supply (e.g., a single-phase power supply) that is configured to provide power to the GPU 120 and/or the memory units 125.

In the illustrated example of FIG. 1, the power components mounted to the second PCB 110 include decoupling capacitors 130, power inductors 135, and phase switches (e.g., MOSFETs or “FETs”) 140. In operation, the phase switches 140 output current to the GPU 120 and/or the memory units 125 via the conductive pillars 115. The decoupling capacitors 130 and power inductors 135 can be coupled to the phase switches 140 and/or the conductive pillars 115 to filter and/or modify the current output by the phase switches 140. In some examples, the decoupling capacitors 130, power inductors 135, and phase switches 140 are coupled in a multiphase power supply arrangement. Persons skilled in the art will understand that the decoupling capacitors 130, the power inductors 135, and the phase switches 140 shown in FIG. 1 are non-limiting examples of power components that can be mounted to or otherwise supported on the second PCB 110. Moreover, persons skilled in the art will understand that, in other examples, the second PCB 110 can support one or more other power components that are not shown in the illustrated example of FIG. 1. In addition, in other examples, the second PCB 110 can support fewer power components or more power components than the number of power components shown in the illustrated example of FIG. 1.

As shown in the illustrated example of FIG. 1, the first PCB 105 is arranged in parallel with the second PCB 110 such that the first and second PCBs 105, 110 extend in substantially the same directions. Furthermore, in the illustrated example of FIG. 1, the first PCB 105 is spaced apart vertically from the second PCB 110 such that the first PCB 105 is disposed underneath the second PCB 110. However, persons skilled in the art will understand that in other examples, the first PCB 105 can be disposed vertically above the second PCB 110. In addition, persons skilled in the art will understand that although the stacked power supply assembly 100 is shown to include only a first PCB 105 and a second PCB 110, in some examples, the stacked power supply assembly 100 can include one or more additional PCBs that are vertically spaced apart form the first and second PCBs 105, 110. In such examples, the one or more additional PCBs can be used to support additional power components, such as additional decoupling capacitors, power inductors, or phase switches, used for powering electronic components such as the GPU 120 and/or the memory units 125.

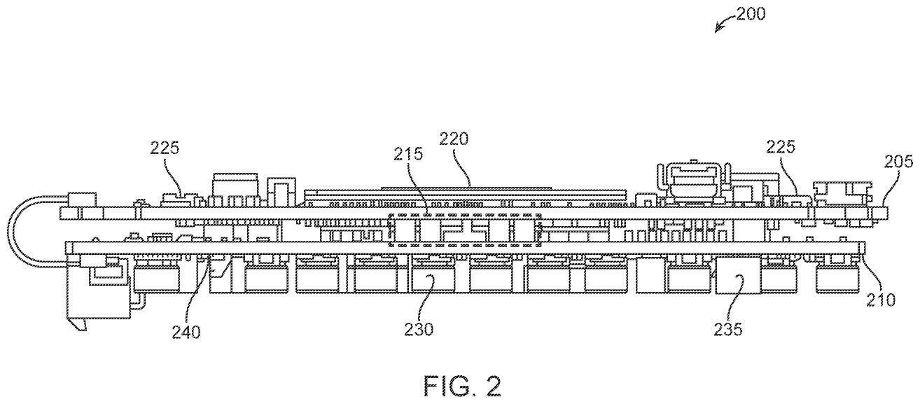

FIG. 2 illustrates an exemplar stacked power supply assembly 200, according to various embodiments. In some examples, the stacked power supply assembly 200 is implemented as the stacked power supply assembly 100 described herein and shown in the illustrated example of FIG. 1. As shown, the stacked power supply assembly 200 includes a first printed circuit board (PCB) 205 and a second PCB 210. The first PCB 205 is vertically spaced apart from the second PCB 210 by a plurality of conductive pillars 215 that electrically couple the first PCB 205 to the second PCB 210. As will be described in more detail herein, the conductive pillars 215 are electrically coupled between respective conductive terminals disposed on the first and second PCBs 205, 210. Persons skilled in the art will understand that number of conductive pillars 215 shown in FIG. 2 is provided as a non-limiting example, and that in other examples, the stacked power supply assembly 200 can include more conductive pillars 215 or fewer conductive pillars 215 than the number of conductive pillars 215 shown in FIG. 2. In some examples, the stacked power supply assembly 200 includes a single conductive pillar 215 that electrically couples the first PCB 205 to the second PCB 210. In other examples, the stack power supply assembly 200 includes a plurality (e.g., two, four, six, nine, ten, twelve, etc.) of conductive pillars 215.

As shown in the illustrated example of FIG. 2, the first PCB 205 is arranged in parallel with the second PCB 210 such that the first and second PCBs 205, 210 extend in substantially the same directions. Furthermore, in the illustrated example of FIG. 2, the first PCB 105 is spaced apart vertically from the second PCB 210 such that the first PCB 205 is disposed above the second PCB 210. However, persons skilled in the art will understand that in other examples, the first PCB 205 can be disposed vertically below the second PCB 210. In addition, persons skilled in the art will understand that although the stacked power supply assembly 200 is shown to include only a first PCB 205 and a second PCB 210, in some examples, the stacked power supply assembly 200 can include one or more additional PCBs that are vertically spaced apart from the first and second PCBs 205, 210.

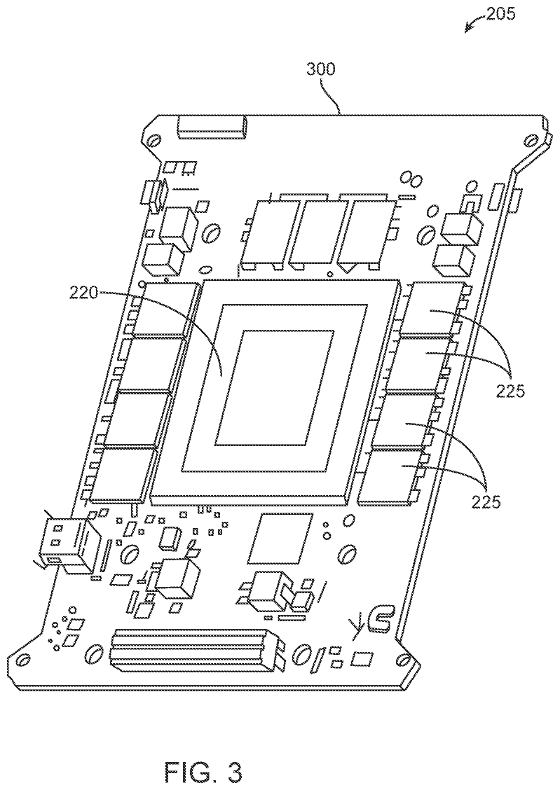

In the illustrated example of FIG. 2, various electronic components are mounted to, or otherwise supported by, the first PCB 205. In particular, a plurality of electronic components are mounted to a first, or top, surface 300 of the first PCB 205. FIG. 3 is a more detailed illustration of the top surface 300 of the first PCB 205 included in the exemplar stacked power supply assembly 200 of FIG. 2, according to various embodiments. As shown in FIGS. 2 and 3, a processor 220 and various memory units 225 are mounted to the top surface 300 of the first PCB 205. Persons skilled in the art will understand that the processor 220 and memory units 225 mounted to the top surface of the first PCB 205 are non-limiting examples of electronic components that can be mounted to the top surface 300 of the first PCB 205. Moreover, persons skilled in the art will understand that, in other examples, one or more of the processor 220, the memory units 225, and/or one or more other electronic components can instead by mounted to the bottom surface of the first PCB 205.

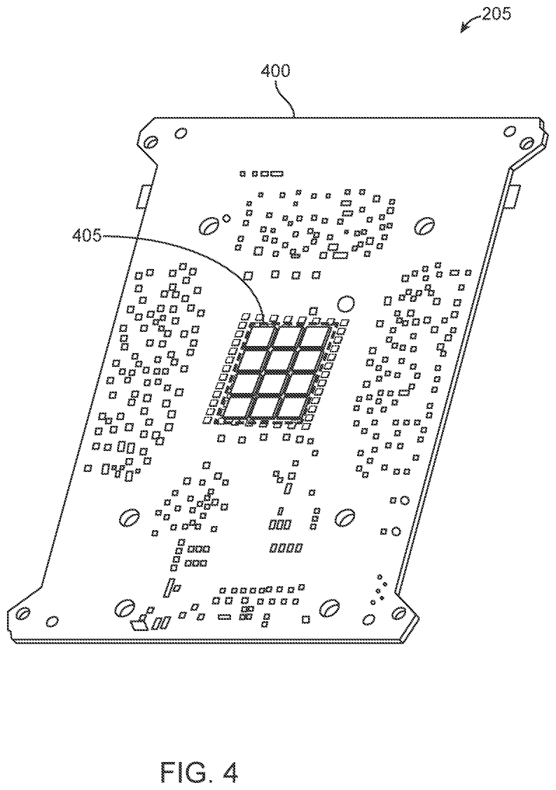

As will be described in more detail herein, the stacked power supply assembly 200 provides operational power to the electronic components, such as the processor 220 and/or memory units 225, mounted to the top surface 300 of the first PCB 205. For example, power components mounted to and/or supported by the second PCB 210 provide operational power to the electronic components mounted to the top surface 300 of the first PCB 205 via the conductive pillars 215 coupled to a second, or bottom, surface 400 of the first PCB 205. FIG. 4 is a more detailed illustration of the bottom surface 400 of the first PCB 205 included in the exemplar stacked power supply assembly 200 of FIG. 2, according to various embodiments. The bottom surface 400 is opposite to the top surface 300. As shown, a plurality of conductive terminals 405 are disposed on the bottom surface 400 of the first PCB 205. The conductive terminals 405 electrically couple the electronic components mounted to the top surface 300 of the first PCB 205 (e.g., processor 220 and/or memory units 225) to the conductive pillars 215. Thus, in operation, the conductive pillars 215 deliver power from the second PCB 210 to the electronic components mounted to the top surface 300 of the first PCB 205 via the conductive terminals 405.

In the illustrated example of FIG. 4, the conductive terminals 405 are illustrated as conductive pads. However, in other examples, the conductive terminals 405 can be implemented as a different type of conductive structure and/or element, such as conductive tabs, pins, or traces. In some examples, the conductive pillars 215 are soldered to the conductive terminals 405. In other examples, the conductive pillars 215 are coupled to the conductive terminals in 405 in a different manner. The conductive terminals 405 are constructed from one or more conductive materials, such as copper, gold, silver, aluminum, and/or one or more other conductive materials. In the illustrated example of FIG. 4, there are twelve conductive terminals 405 disposed on the bottom surface 400 of the first PCB 205. However, persons skilled in the art will understand that in other examples, more or fewer than twelve conductive terminals 405 are disposed on the bottom surface 400 of the first PCB 205. In some examples, the number of conductive terminals 405 disposed on the bottom surface 400 of the first PCB 205 is equal to the number of conductive pillars 215 included in the stacked power supply assembly 200. Furthermore, in some examples, the conductive terminals 405 can instead be disposed on the top surface 300 of the first PCB 205. In such examples, the electronic components can be mounted to the bottom surface 400 of the first PCB 205 and the first PCB 205 can be disposed vertically beneath the second PCB 210.

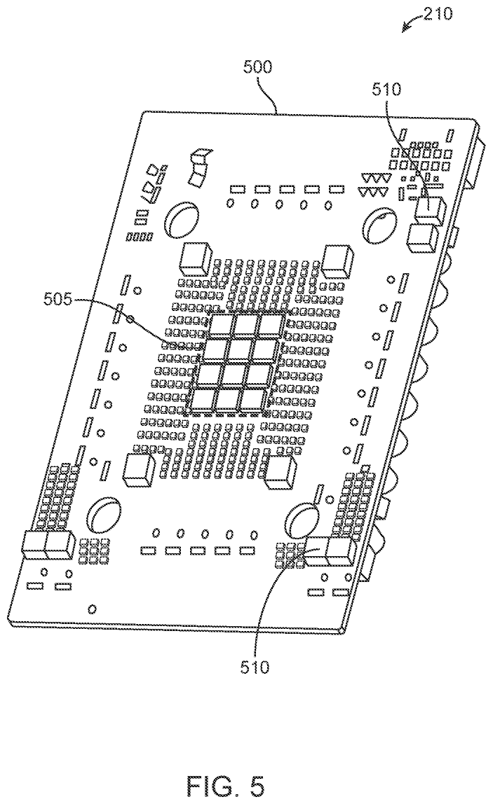

As described above, in operation, the second PCB 210 can provide power to one or more electronic components mounted to the top surface 300 of the first PCB 205 via the conductive pillars 215. For example, power components mounted to and/or supported by the second PCB 210 provide operational power to the electronic components mounted to the top surface 300 of the first PCB 205 via the conductive pillars 215 coupled to a first, or top, surface 500 of the second PCB 210. FIG. 5 is a more detailed illustration of the top surface 500 of the second PCB 210 included in the exemplar stacked power supply assembly 200 of FIG. 2, according to various embodiments. As shown, a plurality of conductive terminals 505 are disposed on the top surface 500 of the second PCB 210. The conductive terminals 505 electrically couple the power components, such as decoupling capacitors 230, power inductors 235, and phase switches 240, mounted to or otherwise supported by a second, or bottom, surface 600 of the second PCB 210 to the conductive pillars 215. In this regard, the conductive pillars 215 deliver power from the power components mounted to the bottom surface 600 of the second PCB 210 to the electronic components mounted to the top surface 300 of the first PCB 205 via the conductive terminals 405 and 505. As further shown in FIG. 5, a plurality of structural support elements 510 are disposed on the top surface 500 of the second PCB 210. The structural support elements 510 support the first PCB 205 such that first PCB 205 is spaced vertically apart from the second PCB 210. For example, the structural support elements 510 support the bottom surface 400 of the first PCB 205 in a position that is spaced apart vertically from the top surface 500 of the second PCB 210. In some examples, the first PCB 205 sit atop the structural support elements 510.

Similar to the conductive terminals 405, in the illustrated example of FIG. 5, the conductive terminals 505 are illustrated as conductive pads. However, in other examples, the conductive terminals 505 can be implemented as a different type of conductive structure and/or element, such as conductive tabs, pins, or traces. In some examples, the conductive pillars 215 are soldered to the conductive terminals 505. In other examples, the conductive pillars 215 are coupled to the conductive terminals 505 in a different manner. The conductive terminals 505 are constructed from one or more conductive materials, such as copper, gold, silver, aluminum, and/or one or more other conductive materials. In the illustrated example of FIG. 5, there are twelve conductive terminals 505 disposed on the bottom surface 400 of the first PCB 205. However, persons skilled in the art will understand that in other examples, more or fewer than twelve conductive terminals 505 are disposed on the top surface 500 of the second PCB 210. In some examples, the number of conductive terminals 505 disposed on the top surface 500 of the second PCB 210 is equal to the number of conductive pillars 215 included in the stacked power supply assembly 200. Furthermore, in some examples, the conductive terminals 505 are disposed on the bottom surface 600 of the second PCB 210. In such examples, the power components can be mounted to the top surface 500 of the second PCB 210 and the second PCB 210 can be disposed vertically above the first PCB 205.

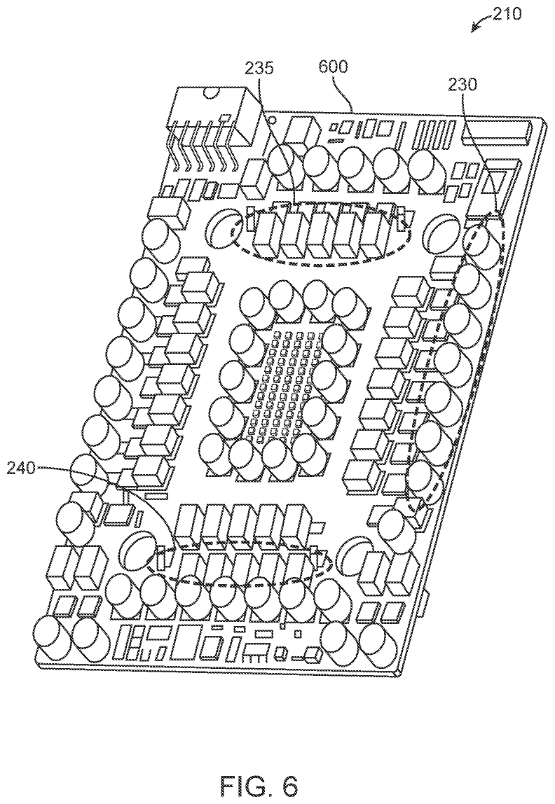

FIG. 6 is a more detailed illustration of the bottom surface 600 of the second PCB 210 included in the exemplar stacked power supply assembly 200 of FIG. 2, according to various embodiments. The bottom surface 600 is opposite to the top surface 500. As shown, a plurality of power components are mounted to or otherwise supported on the bottom surface 600 of the second PCB 210. In the illustrated example of FIG. 6, the power components mounted to the bottom surface 600 of the second PCB 210 include decoupling capacitors 230, power inductors 235, and phase switches 240. Persons skilled in the art will understand that that the decoupling capacitors 230, power inductors 235, and phase switches 240 are non-limiting examples of power components that can be included in the stacked power supply assembly 200. Moreover, persons skilled in the art will understand that more or fewer power components that the power components shown in the illustrated example of FIG. 6 can be mounted to the bottom surface 600 of the second PCB 210. In some examples, the power components are included in a multiphase power supply mounted to the bottom surface 600 of the second PCB 210.

As described herein, the power components mounted to the bottom surface 600 of the second PCB 210 (e.g., decoupling capacitors 230, power inductors 235, and phase switches 240) provide operational power to the electronic components mounted to the top surface 300 of the first PCB 205 via the conductive pillars 215. For example, the phase switches 240, which are coupled to the conductive terminals 505, output current to the conductive pillars 215 via the conductive terminals 505. The conductive pillars 215 then deliver the current output by the phase switches 240 to the electronic components mounted to the top surface 300 of the first PCB 205 (e.g., the processor 220 and/or the memory units 225) via the conductive terminals 405. In some examples, the phase switches 240 are coupled to the conductive terminals 505 by respective power inductors 235. In such examples, current output by a phase switch 240 flows through a power inductor 235 to the conductive terminals 505. The decoupling capacitors 230, which can be coupled to the phase switches 240 and/or the power inductors 235, help stabilize power provided from the second PCB 210 to the first PCB 205 and improve transient performance of the stacked power supply assembly 200.

Since the second PCB 210 supports the power components and the first PCB 205 supports one or more electronic components that are powered by the power components supported on the second PCB 210, in some examples, the first and second PCBs 205, 210 can be constructed from different materials. For example, the first PCB 205 can be constructed from one or more first materials that are better suited to high-speed signal transmission and the second PCB 210 can be constructed from one or more second materials that are better suited to low-loss power delivery. In some examples, the first PCB 205 can be constructed from one or more materials that are suited for the transmission of high-speed signals such as, but not limited to, EM-370(5), EM-370D, EM-355D, NPG-151, and/or R1566-WN. As another example, the second PCB 210 can be constructed from one or more low-loss PCB materials such as, but not limited to, EM-528, EM890, EM-890K, LW-900G, LW-910G. IT-988G NPG-186, NPG-199, NPG-199K, and/or M6N HF. In some examples, the first PCB 205 and the second PCB 210 can be constructed from the same materials.

In the illustrated examples of FIGS. 1 and 2, the conductive pillars 115, 215 are respectively illustrated as solid rectangular blocks formed of conductive material such as, but not limited to, copper. However, in some examples, the conductive pillars 115 included in the stacked power supply assembly 100 and/or the conductive pillars 215 included in the stacked power supply assembly 200 have different shapes and/or structures. For example, instead of having a rectangular block shape, in some examples, a conductive pillar 115, 215 can have a rounded shape, a cylindrical shape, a helical shape, or any other shape suitable for transmitting power between PCBs.

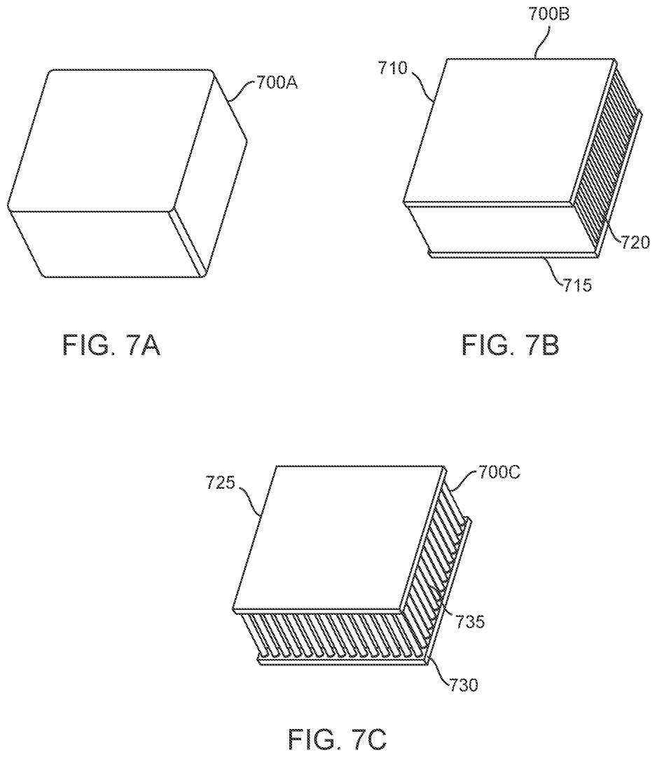

FIGS. 7A-7C illustrate different exemplar conductive pillar structures that can be implemented in a stacked power supply assembly, according to various embodiments. The different exemplar pillar structures illustrated in FIGS. 7A-7C can be, for example, used to implement the conductive pillars 115 included in the stacked power supply assembly 100 and/or the conductive pillars 215 included in the stacked power supply assembly 200 described herein. FIG. 7A illustrates a first conductive pillar structure 700A that can be used to implement the conductive pillars 115 included in the stacked power supply assembly 100 and/or the conductive pillars 215 included in the stacked power supply assembly 200 described herein. As shown in FIG. 7A, the first conductive pillar structure 700A is a solid rectangular block formed of conductive material such as copper.

FIG. 7B illustrates a second conductive pillar structure 700B that that can be used to implement the conductive pillars 115 included in the stacked power supply assembly 100 and/or the conductive pillars 215 included in the stacked power supply assembly 200 described herein. As shown in FIG. 7B, the second conductive pillar structure 700B is a rectangular block that comprises a first surface 710, a second surface 715, and a plurality of fins 720 disposed between first surface 710 and the second surface 715. The fins 720 electrically couple the first surface 710 to the second surface 715 such that current flows between the first and second surfaces 710, 715 via the fins 720. The fins 720 are respectively spaced apart from each other such that air or some other resistive material is disposed between adjacent fins 720. When compared to the first conductive pillar structure 700A, the surface area of conductive material included in the second conductive pillar structure 700B is increased. In this regard, the resistance of the second conductive pillar structure 700B is reduced at higher frequencies, and thus, the second conductive pillar structure 700B experiences fewer losses than the first conductive pillar structure 700A at high frequencies.

FIG. 7C illustrates a third conductive pillar structure 7000 that that can be used to implement the conductive pillars 115 included in the stacked power supply assembly 100 and/or the conductive pillars 215 included in the stacked power supply assembly 200. As shown in FIG. 7C, the third conductive pillar structure 7000 is a rectangular block that comprises a first surface 725, a second surface 730, and a plurality of pins 735 disposed between first surface 725 and the second surface 730. The pins 735 electrically couple the first surface 725 to the second surface 730 such that current flows between the first and second surfaces 725, 730 via the pins 735. The pins 735 are respectively spaced apart from each other such that air or some other resistive material is disposed between adjacent pins 735. When compared to the first conductive pillar structure 700A, the surface area of conductive material included in the third conductive pillar structure 7000 is increased. In this regard, the resistance of the third conductive pillar structure 7000 is reduced at higher frequencies, and thus, the third conductive pillar structure 7000 experiences fewer losses than the first conductive pillar structure 700A at high frequencies.

When compared to conventional power supply assemblies in which electrical components and the power components that provide power to the electrical components are mounted to and/or supported on the same PCB, the PCBs included in the stacked power assemblies 100, 200 described herein have smaller surface areas. In this regard, the PCBs included in the stacked power supply assemblies 100, 200 impede the flow of cooling air forced over the stacked power supply assemblies 100, 200 by a fan less than an amount by which a PCB included in a conventional power supply assembly impedes the flow of cooling air. Therefore, a fan can more effectively remove heat from the stacked power supply assemblies 100, 200 described herein, as cooling air forced by the fan has more space to flow without being recirculated.

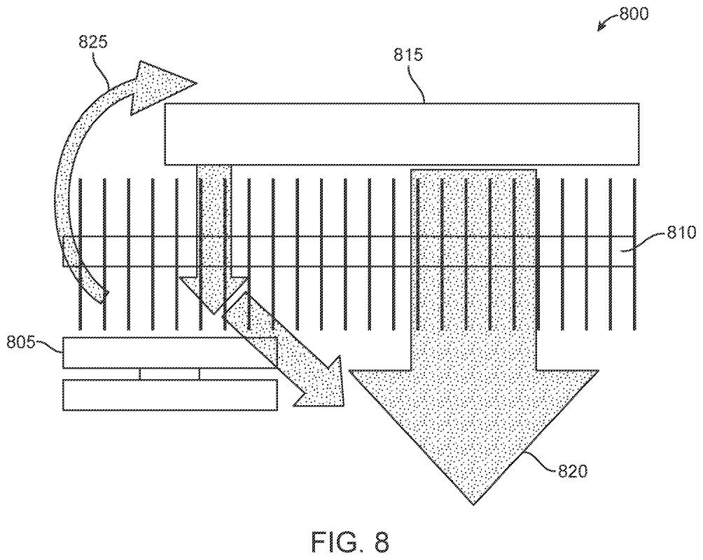

FIG. 8 illustrates a cooling system 800 for a stacked power supply assembly 805, according to various embodiments. In some examples, the stacked power supply assembly 805 is implemented as one of the stacked power supply assemblies 100, 200 described herein. As shown in FIG. 8, the cooling system 800 includes a heat sink 810 that is thermally coupled to the stacked power supply assembly 805 and fan 815 that is configured to force cooling air over the heat sink 810 in a first direction 820 towards the stacked power supply assembly 805. The heat sink 810 can be implemented as any suitable type of heat sink, such as a heat pipe, a vapor chamber, a metal plate, a fin stack, and/or some other type of heat sink. Although illustrated as including a single fan 815, in some examples, the cooling system 800 can includes two or more fans configured to force cooling air over the heat sink 810.

In operation, the stacked power supply assembly 805 generates heat. The heat generated by the stacked power supply assembly 805 is transferred to and dissipated by the heat sink 810. The fan 815 forces cooling air over the heat sink 810 in the first direction 820 to remove heat from heat sink 810 and force the removed heat away from the stacked power supply assembly 805. As shown in FIG. 8, the reduced surface area of the PCBs included in the stacked power supply assembly 805 provides relatively little impedance to the flow of cooling air in the first direction 805. Accordingly, only a relatively small portion of the cooling air forced by the fan 815 over the heat sink 810 is impeded by the stacked power supply assembly 805 and recirculated 825 towards the fan 805. In this regard, the reduced surface areas of the PCBs included in the stacked power supply assembly 805 enables the fan 815 to remove more heat from the heat sink 810 and stacked power supply assembly 805 when compared to a conventional power supply assembly in which the electronic components and power components are mounted to the same PCB.

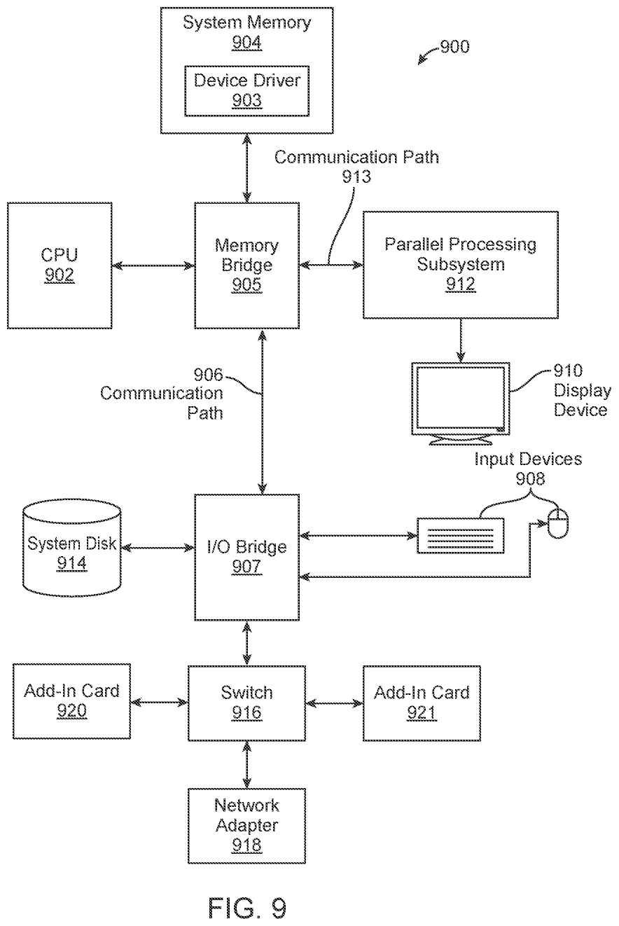

FIG. 9 illustrates a computer system 900 configured to implement one or more aspects of the various embodiments. In some embodiments, computer system 900 is a machine or processing node operating in a data center, cluster, or cloud computing environment that provides scalable computing resources (optionally as a service) over a network. In some embodiments, the computer system 900 is a high-performance computing system or device such as, without limitation, a server machine, a server platform, a desktop machine, a laptop machine, a hand-held/mobile device, or a wearable device. As will be described in more detail below, the computer system 900 includes one or more electronic components that can be powered by one or more stacked power supply assemblies, such as stacked power supply assembly 100 and/or stacked power supply assembly 200, described herein with respect to FIGS. 1-8. Stated another way, the computer system 900 includes and/or is coupled to one or more stacked power supply assemblies described herein that are used to power one or more of the electronic components of the computer system 900. For example, one or more electronic components of the computer system 900 can be mounted to a first PCB, such as the first PCB 105 or the first PCB 205, included in a stacked power supply assembly described herein and powered by the power components mounted to or otherwise supported by a second PCB, such as the second PCB 110 or the second PCB 210, included in a stacked power supply assembly described herein.

In various embodiments, computer system 900 includes, without limitation, a central processing unit (CPU) 902 and a system memory 904 coupled to a parallel processing subsystem 912 via a memory bridge 905 and a communication path 913. Memory bridge 905 is further coupled to an I/O (input/output) bridge 907 via a communication path 906, and I/O bridge 907 is, in turn, coupled to a switch 916. In operation of the computer system 900, one or more of the CPU 902, the system memory 904, and/or the parallel processing subsystem 912 can be coupled to and powered by a stacked power supply assembly, such as the stacked power supply assembly 100 and/or the stacked power supply assembly 200, described herein with respect to FIGS. 1-8.

In one embodiment, I/O bridge 907 is configured to receive user input information from optional input devices 908, such as a keyboard or a mouse, and forward the input information to CPU 902 for processing via communication path 906 and memory bridge 905. In some embodiments, computer system 900 may be a server machine in a cloud computing environment. In such embodiments, computer system 900 may not have input devices 908. Instead, computer system 900 may receive equivalent input information by receiving commands in the form of messages transmitted over a network and received via the network adapter 918. In one embodiment, switch 916 is configured to provide connections between I/O bridge 907 and other components of the computer system 900, such as a network adapter 918 and various add-in cards 920 and 921.

In one embodiment, I/O bridge 907 is coupled to a system disk 914 that may be configured to store content and applications and data for use by CPU 902 and parallel processing subsystem 912. In one embodiment, system disk 914 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. In various embodiments, other components, such as universal serial bus or other port connections, compact disc drives, digital versatile disc drives, film recording devices, and the like, may be coupled to I/O bridge 907 as well.

In various embodiments, memory bridge 905 may be a Northbridge chip, and I/O bridge 907 may be a Southbridge chip. In addition, communication paths 906 and 913, as well as other communication paths within computer system 900, may be implemented using any technically suitable protocols, including, without limitation, AGP (Accelerated Graphics Port), HyperTransport, or any other bus or point-to-point communication protocol known in the art.

In some embodiments, parallel processing subsystem 912 includes a graphics subsystem that delivers pixels to an optional display device 910 that may be any conventional cathode ray tube, liquid crystal display, light-emitting diode display, or the like. In such embodiments, the parallel processing subsystem 912 incorporates circuitry optimized for graphics and video processing, including, for example, video output circuitry. Such circuitry may be incorporated across one or more parallel processing units (PPUs), also referred to herein as parallel processors, included within parallel processing subsystem 912. In other embodiments, the parallel processing subsystem 912 incorporates circuitry optimized for general purpose and/or compute processing. Again, such circuitry may be incorporated across one or more PPUs included within parallel processing subsystem 912 that are configured to perform such general purpose and/or compute operations. In yet other embodiments, the one or more PPUs included within parallel processing subsystem 912 may be configured to perform graphics processing, general purpose processing, and compute processing operations. System memory 904 includes at least one device driver 903 configured to manage the processing operations of the one or more PPUs within parallel processing subsystem 912. In some embodiments, the one or more PPUs can be powered by one or more stacked power supply assemblies, such as one or more of the stacked power supply assemblies 100, 200 described herein with respect to FIGS. 1-8.

In various embodiments, parallel processing subsystem 912 may be integrated with one or more of the other elements of FIG. 9 to form a single system. For example, parallel processing subsystem 912 may be integrated with CPU 902 and other connection circuitry on a single chip to form a system on chip (SoC).

In one embodiment, CPU 902 is the master processor of computer system 900, controlling and coordinating operations of other system components. In one embodiment, CPU 902 issues commands that control the operation of PPUs. In some embodiments, communication path 913 is a PCI Express link, in which dedicated lanes are allocated to each PPU, as is known in the art. Other communication paths may also be used. PPU advantageously implements a highly parallel processing architecture. A PPU may be provided with any amount of local parallel processing memory (PP memory).

It will be appreciated that the system shown herein is illustrative and that variations and modifications are possible. The connection topology, including the number and arrangement of bridges, the number of CPUs 902, and the number of parallel processing subsystems 912, may be modified as desired. For example, in some embodiments, system memory 904 could be coupled to CPU 902 directly rather than through memory bridge 905, and other devices would communicate with system memory 904 via memory bridge 905 and CPU 902. In other embodiments, parallel processing subsystem 912 may be coupled to I/O bridge 907 or directly to CPU 902, rather than to memory bridge 905. In still other embodiments, I/O bridge 907 and memory bridge 905 may be integrated into a single chip instead of existing as one or more discrete devices. Lastly, in certain embodiments, one or more components shown in FIG. 9 may not be present. For example, switch 916 could be eliminated, and network adapter 918 and add-in cards 920, 921 would connect directly to I/O bridge 907.

In sum, a stacked power supply assembly that includes a first printed circuit board (PCB) and a second PCB that is spaced apart vertically from the first PCB. The first PCB includes one or more first terminals that are electrically coupled to one or more second terminals of the second PCB by one or more conductive pillars disposed between the first and second PCBs. In this regard, the one or more conductive pillars electrically couple the first PCB to the second PCB. In operation, one or more power components mounted to or otherwise supported on the second PCB provide power to one or more electronic components mounted to or otherwise supported by the first PCB.

At least one technical advantage of the disclosed stacked power supply assemblies relative to the prior art is that, in the disclosed designs, the surface areas of the PCBs included in the stacked power supply assemblies are reduced. Accordingly, the phase switches can be positioned closer to the load to which the phase switches deliver power, thereby reducing the amount of copper losses in the disclosed stacked power supply assembly. Moreover, the reduced surface areas of the PCBs reduces the impedance experienced by the cooling air forced over the stacked power supply assembly by a fan, which improves the overall thermal efficiency of the disclosed stacked power supply assembly. Another technical advantage of the disclosed design is that the power components, such as phase switches, inductors, and capacitors, and the load powered by those power components are supported on different PCBs. Consequently, an increased number of decoupling capacitors can be positioned near the load, which lowers the resistance and improves the overall transient performance of the disclosed stacked power supply assembly. In addition, because of the use of different PCBs in the disclosed stacked power supply assembly, the PCB that supports the power components can be constructed from materials that are better suited for overall power delivery. These technical advantages represent one or more technological improvements over prior art approaches.

1. In some embodiments, a power supply assembly comprises a first printed circuit board (PCB), a second PCB that is vertically spaced apart from the first PCB, a switch supported on the second PCB, and a conductive pillar that couples the first PCB to the second PCB, wherein current output by the switch flows from the switch to the first PCB via the conductive pillar.

2. The power supply assembly of clause 1, further comprising an inductor supported on the second PCB, wherein the inductor is coupled between the switch and the conductive pillar.

3. The power supply assembly of clauses 1 or 2, further comprising a capacitor supported on the second PCB, wherein the capacitor is coupled to the switch and the conductive pillar.

4. The power supply assembly of any of clauses 1-3, further comprising a second conductive pillar that couples the first PCB to the second PCB.

5. The power supply assembly of any of clauses 1-4, wherein the conductive pillar and the second conductive pillar are disposed between the first PCB and the second PCB.

6. The power supply assembly of any of clauses 1-5, wherein the first PCB is arranged in parallel with the second PCB.

7. The power supply assembly of any of clauses 1-6, wherein the first PCB comprises a first material and the second PCB comprises a second material different than the first material.

8. The power supply assembly of any of clauses 1-7, wherein the conductive pillar comprises copper.

9. The power supply assembly of any of clauses 1-8, wherein the conductive pillar comprises a plurality of pins.

10. The power supply assembly of any of clauses 1-9, wherein the conductive pillar comprises a plurality of fins.

11. In some embodiments, a power supply assembly comprises a first printed circuit board (PCB) that includes a first terminal disposed on a first surface of the first PCB, a second PCB that includes a second terminal disposed on a first surface of the second PCB, wherein the first surface of the second PCB is parallel to the first surface of the first PCB, and a conductive pillar that electronically couples the first terminal to the second terminal.

12. The power supply assembly of clause 11, wherein the first terminal comprises at least one of copper, gold, silver, or aluminum.

13. The power supply assembly of clauses 11 or 12, wherein a multiphase power supply is supported on a second surface of the second PCB and electrically coupled to the second terminal.

14. The power supply assembly of any of clauses 11-13, wherein an electronic component is mounted to a second surface of the first PCB and electrically coupled to the first terminal.

15. The power supply assembly of any of clauses 11-14, wherein the multiphase power supply is configured to provide current to the electronic component via the conductive pillar.

16. The power supply assembly of any of clauses 11-15, wherein the multiphase power supply includes a plurality of phase switches, a plurality of capacitors, and a plurality of inductors.

17. The power supply assembly of any of clauses 11-16, wherein a switch is mounted to a second surface of the second PCB and electrically coupled to the second terminal.

18. In some embodiments, a system comprises a first printed circuit board (PCB), an electronic component supported on the first PCB, a second PCB that is vertically spaced apart from the first PCB, one or more switches supported on the second PCB, and one or more conductive pillars disposed between the first PCB and the second PCB, wherein the one or more conductive pillars electronically couple the one or more switches to the electronic component.

19. The system of clause 18, further comprising a heat sink that is thermally coupled to at least one of the first PCB or the second PCB.

20. The system of clauses 18 or 19, further comprising a fan arranged to force air over the first PCB and the second PCB.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. A power supply assembly, comprising:
a first printed circuit board (PCB);
a second PCB that is vertically spaced apart from the first PCB;
a switch supported on the second PCB; and
a conductive pillar that couples the first PCB to the second PCB, wherein current output by the switch flows from the switch to the first PCB via the conductive pillar.

2. The power supply assembly of claim 1, further comprising an inductor supported on the second PCB;
wherein the inductor is coupled between the switch and the conductive pillar.

3. The power supply assembly of claim 1, further comprising a capacitor supported on the second PCB;
wherein the capacitor is coupled to the switch and the conductive pillar.

4. The power supply assembly of claim 1, further comprising a second conductive pillar that couples the first PCB to the second PCB.

5. The power supply assembly of claim 4, wherein the conductive pillar and the second conductive pillar are disposed between the first PCB and the second PCB.

6. The power supply assembly of claim 1, wherein the first PCB is arranged in parallel with the second PCB.

7. The power supply assembly of claim 1, wherein the first PCB comprises a first material and the second PCB comprises a second material different than the first material.

8. The power supply assembly of claim 1, wherein the conductive pillar comprises copper.

9. The power supply assembly of claim 1, wherein the conductive pillar comprises a plurality of pins.

10. The power supply assembly of claim 1, wherein the conductive pillar comprises a plurality of fins.

11. A power supply assembly, comprising:
a first printed circuit board (PCB) that includes a first terminal disposed on a first surface of the first PCB;
a second PCB that includes a second terminal disposed on a first surface of the second PCB, wherein the first surface of the second PCB is parallel to the first surface of the first PCB; and
a conductive pillar that electronically couples the first terminal to the second terminal.

12. The power supply assembly of claim 11, wherein the first terminal comprises at least one of copper, gold, silver, or aluminum.

13. The power supply assembly of claim 11, wherein a multiphase power supply is supported on a second surface of the second PCB and electrically coupled to the second terminal.

14. The power supply assembly of claim 13, wherein an electronic component is mounted to a second surface of the first PCB and electrically coupled to the first terminal.

15. The power supply assembly of claim 14, wherein the multiphase power supply is configured to provide current to the electronic component via the conductive pillar.

16. The power supply assembly of claim 13, wherein the multiphase power supply includes a plurality of phase switches, a plurality of capacitors, and a plurality of inductors.

17. The power supply assembly of claim 11, wherein a switch is mounted to a second surface of the second PCB and electrically coupled to the second terminal.

18. A system, comprising:
a first printed circuit board (PCB);
an electronic component supported on the first PCB;
a second PCB that is vertically spaced apart from the first PCB;
one or more switches supported on the second PCB; and
one or more conductive pillars disposed between the first PCB and the second PCB, wherein the one or more conductive pillars electronically couple the one or more switches to the electronic component.

19. The system of claim 18, further comprising a heat sink that is thermally coupled to at least one of the first PCB or the second PCB.

20. The system of claim 18, further comprising a fan arranged to force air over the first PCB and the second PCB.
